(19) United States
(12) Patent Application Publication
(10) Pub. No.: US 2002/0127865 A1
(43) Pub. Date: Sep. 12, 2002

(54) Lithography method for forming semiconductor devices with sub-micron structures on a wafer and apparatus

(75) Inventors: John George Maltabes, Austin, TX (US); Alain Bernard Charles, Singapore (SG); Karl Emerson Mautz, Round Rock, TX (US)

Correspondence Address: Jim Clingan, Motorola, Inc., Austin Intellectual Property Law Section, 7700 West Parmer Lane, Austin, TX, 78729, US

(73) Assignee: Motorola, Inc.

(21) Appl. No.: 09/801,521

(22) Filed: Mar. 8, 2001

(51) Int. Cl. G03C 5/00; G03F 7/00; H01L 21/311; C23F 1/02

(52) U.S. Cl. 438/694; 430/30; 430/313; 430/315; 156/345.24

(57) ABSTRACT

In a lithography method with the steps coating (13) a lithography resist onto a wafer, exposing (14) the wafer, stabilizing (16), performing (17) a metrology inspection of the resulting lithography resist pattern, etching, and wet processing or implanting ions (18), for exposing, a reticle is aligned with respect to the wafer by atomic force microscopy in an atomic force microscopy (AFM) module (11).

### RELATED APPLICATION

This application is related to the commonly assigned application entitled “LITHOGRAPHY METHOD FOR FORMING SEMICONDUCTOR DEVICES ON A WAFER AND APPARATUS”, also filed by applicants Maltabes et al. in the United States Patent and Trademark Office, identified by docket number SC0198WD.

### FIELD OF THE INVENTION

The present invention generally relates to large scale integration semiconductor devices and in particular, though not exclusively, to a lithography method for forming semiconductor devices with sub-micron structures on a wafer and an apparatus for it.

### BACKGROUND OF THE INVENTION

As lithography exposure tools become increasingly complex due to the use of sub-DUV wavelengths, this will require use of vacuum in the lithography chamber or optical exposure area. This includes such lithography technologies as X-ray, electron beam, ion beam projection and extreme ultraviolet (EUV). Electron beam alignment systems will use backscattered electrons to calculate offsets. Due to the geometry of alignment marks and detectors, low signal strength, absorption by wafer materials, and low k dielectric film charging may inhibit this technique.

As the device geometries shrink, the requirements for alignment become increasingly stringent and require more precision. In addition to the difficulty in achieving the accurate stacking, the ability to determine the alignment marks is beginning to reach the limits of optical detection techniques.

The present invention seeks to provide a concept for replacing conventional optical alignment systems by a newer technique which mitigates or avoids the disadvantages and limitations of the prior art.

### BRIEF DESCRIPTION OF THE DRAWINGS

FIG. 1 illustrates a lithography apparatus according to prior art;

FIG. 2 illustrates a lithography apparatus according to an embodiment of the present invention;

FIG. 3 is a flowchart of the lithography process for forming a semiconductor device with sub-micron structures on a wafer according to prior art; and

FIG. 4 is a part of the flowchart of FIG. 3 in detail that embodies the present invention.

### DETAILED DESCRIPTION OF A PREFERRED EMBODIMENT

According to the present invention the conventional alignment system is replaced with an alignment technique that is based on atomic force microscopy (AFM). The microscopy module is located within the lithography cell. This tool provides for atomic scale alignment accuracy. One advantage of the proposed technique is that this system is not prone to the errors associated with optical metrology such as reflection or scattering. Even an overlaying film above the marks is not perfectly planar and shows elevations at the respective positions of the underlying alignment marks. Thus the marks are still detectable by AFM.

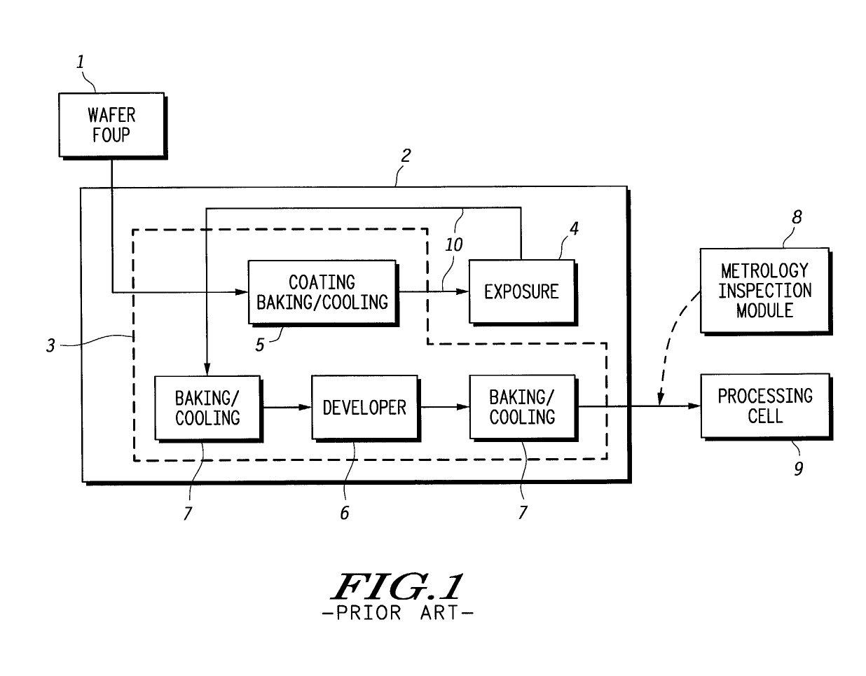

Referring to FIG. 1, there is shown a prior art design of a lithography cell and relevant adjacent tools. The wafers to be processed are carried in a Front Opening Unified Pod (FOUP) 1 which contains e.g. 25 wafers of 300 mm diameter. The wafer FOUP 1 enters into a lithography cell 2 which comprises as main components a coater tool 3 and an exposure tool 4. The lithography cell 2 is indicated by a rectangle with bold lines which encompasses the coater tool 3 and the exposure tool 4 as its components. The coater tool 3 is indicated by a polygon with dashed lines, it comprises a coating means 5, a developer means 6 and a stabilization means 7 for baking/cooling the wafer. (In the following the term “baking” the wafer is meant to comprise also subsequent “cooling” of the wafer.) After finishing the processing steps in the lithography cell 2 the wafer is passed on to a processing cell 9 for etching, wet processing or ion implantation.

The tools for lithography processing of the wafer are arranged in a loop, the transportation paths 10 of the wafers between two adjacent processing means being indicated by solid lines (arrows). The wafer first enters the coating means 5 in the coater tool 3, where it is coated with a lithography resist. After the coating the wafer is passed on to said exposure tool 4, which is normally external to the coating tool 3 since, concerning the physical environment, the requirements for the exposure (vacuum) are different from the requirements for coating, developing and baking/cooling. In the exposure tool 4 the wafer is exposed to irradiation with light, X-rays, electrons or ions through a reticle (not shown). After the exposure in the exposure tool 4 the wafer is returned to the coater tool 3 where it is baked and cooled in order to stabilize the exposed lithography resist on it in a first stabilization means 7. The wafer then enters the developer means 6 in which it is developed and afterwards it is passed on to a second stabilization means 7 for baking the resist pattern on the surface of the wafer. Accordingly, there are multiple wafers concurrently processed at one time: such as one in the coating means 5, being coated with resist, one in the exposure tool 4, being irradiated with light, electrons, ions etc., and one in the developer means 6 or the stabilization means 7. After the stabilization means 7 the wafer exits the lithography cell 2 and enters the processing cell 9 (such as an etcher, an ion implanter or similar) for further processing.

Before the wafer enters the processing cell 9, a metrology inspection of the patterns on its surface is carried out, in order to reject wafers with features on their surface that are not properly aligned with respect to the wafer because a misalignment of the wafer and processing means in the lithography cell occurred during the preceding lithography processing. This metrology inspection is carried out in a separate metrology inspection tool 8, external to the lithography cell 2 and the processing cell 9, respectively.

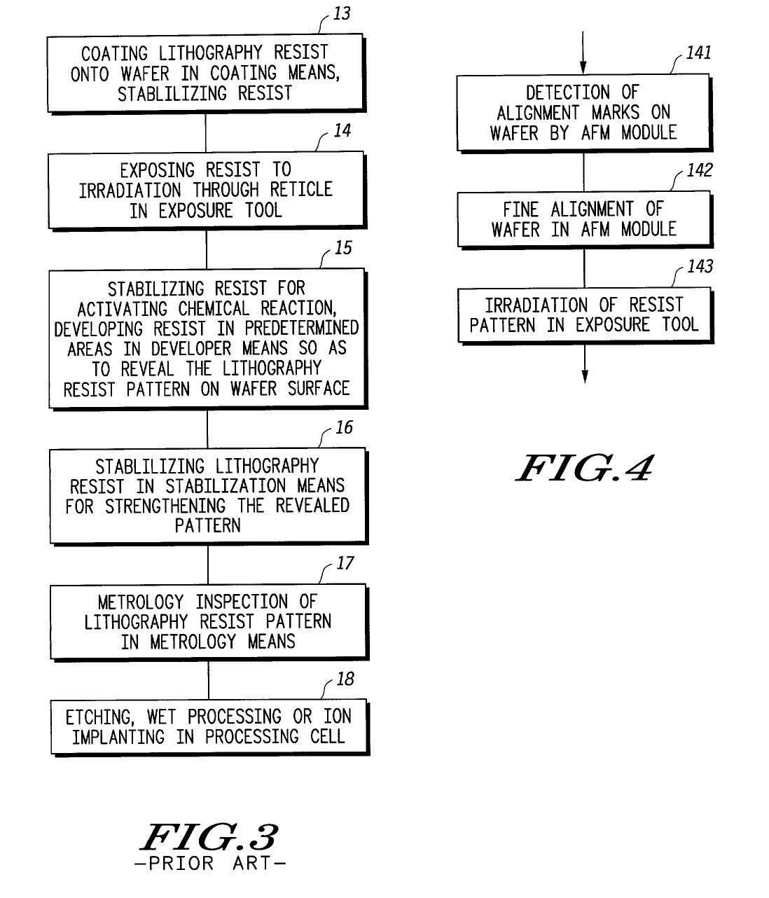

The according steps of the pertaining prior art process are presented in FIG. 3. Referring to FIG. 3, in an initial step 13 a lithography resist is coated onto the wafer in said coating means 5. Subsequently, at step 14, the wafer with the resist on it is exposed to irradiation with deep UV light, extreme UV light, X-rays, electron or ion beams in the exposure tool 4 through a reticle (not shown). After exposure the resist is developed in the developer means 6 at step 15. (In order to stabilize the resist there may be provided a post exposure bake before developing the resist in a first stabilizing means 7.) The developed lithography resist is stabilized by baking and subsequent cooling in the stabilization means 7 at step 16. After the following metrology inspection in the according module 8 at step 17 the batch of wafers is passed on to the processing cell 9. In the processing cell 9 the wafer is etched, wet processed or ion implanted at step 18. It is essential for the lithography processing that the wafer be correctly aligned when it enters the exposure tool on a vacuum chuck that is mounted on a stage. The wafer has to be aligned with respect to the irradiation system in the exposure tool, that is the optical column in the exposure tool comprising the reticle and an irradiation source (not shown). Since this alignment becomes more and more complex with decreasing structure dimensions on the wafer there is provided a different technique for the alignment according to the invention.

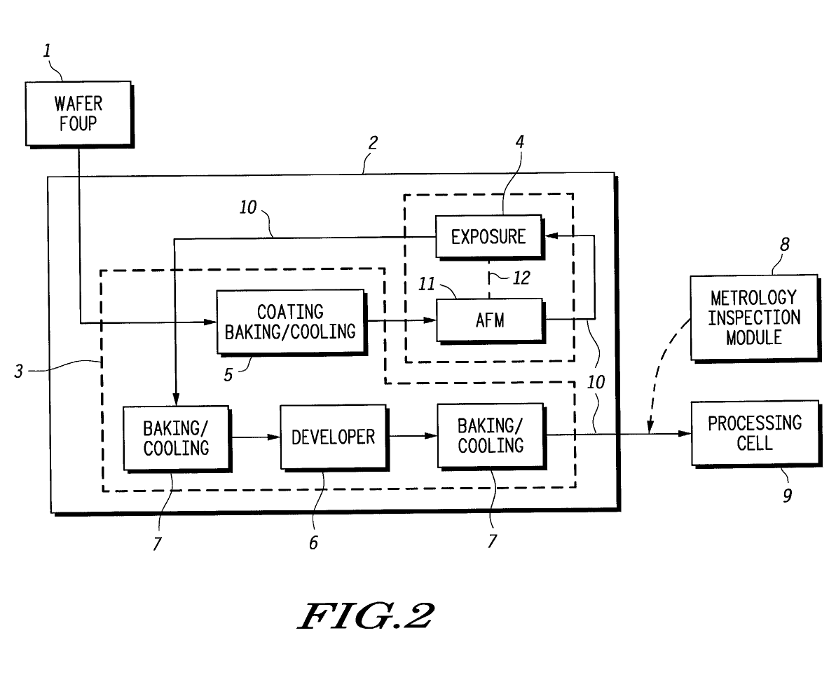

The apparatus for forming at least one semiconductor device on the wafer according to the invention is schematically illustrated in FIG. 2. The lithography apparatus in FIG. 2 comprises substantially the same elements as the one in FIG. 1, but there is provided an atomic force microscopy module 11 before the exposure tool 4 in the lithography cell 2. In fact, the atomic force microscopy module 11 is directly integrated into the exposure tool 4, and AFM is used as assistance for the alignment of the wafer within the exposure tool 4. Before the wafer is mounted on the exposure chuck, its orientation with regard to the chuck is determined by notches on the wafer and a mechanical pre-alignment is carried out off the stage in a separate module (not shown). In two steps, the stage is thereafter aligned with the irradiation system, and the wafer on the chuck is aligned with the stage by the atomic force microscopy module 11. The coarse alignment is typically done first by means of the existing optical system (which is the main adjustment aid with the prior art for aligning the wafer with respect to the optical column, not shown), whereas, according to the invention, the fine adjustment is based on the AFM module 11. To that order the stage is moved from the optical column to the AFM module 11 where the position of the alignment marks are accurately determined. The AFM module 11 detects one or more of the alignment marks on the wafer and compares their every position to respective target positions. In response to the difference between an actual alignment mark position and the target position, an alignment signal is produced and fed into the exposure tool 4 by the AFM module 11 so as to carry out the fine adjustment of the wafer.

The according signals are exchanged between the AFM module 11 and the exposure tool 4 on a bus that is indicated by the dash-dotted line 12 in FIG. 2. The signals comprise information on the lateral displacement (i.e. x- and y-displacement) and on the angular displacement (Θ-displacement) of the wafer. Due to the information from the AFM module 11, the alignment of the wafer can be performed in “real time”. So cost and complexity of the alignment system is reduced to a minimum.

Thereafter the wafer is returned to the optical column in the exposure tool 4 for exposure.

The styli of the atomic force microscopy module are located at a plurality of positions on the stage so as to provide for a higher inspection performance and a higher throughput of wafers. The positions of the styli reach preset areas on the wafer to obtain measurements on normal sites. In a preferred embodiment, instead of any alignment marks, the patterns on the wafer surface are used for the fine alignment of the tool by AFM that are created by a preceding lithography process. Hence, the stylus positions are arranged in such a manner on the stage that their tips reach the patterns on the wafer surface. These patterns are then referred to as alignment marks, and the wafer is adjusted with respect to the optical column, comprising lenses and the reticle, on the basis of such patterns. This frees up space in the scribe grid (kerf) areas. With the alignment of actual die critical geometries, the device performance and yield is thus improved. In a preferred embodiment AFM stylus tips consist of buckyballs, SiC material, and diamond material as the basic components, that are relatively inexpensive and easy to make. Moreover, with microelectro-mechanical systems (MEMS), the design and realization of AFM arrays is inexpensive and simultaneous measurements at any desired spacing are feasible. The atomic force microscope 11 comprises piezo-driven cantilevers with a tip at the free end of it (e.g., either SiC tips, diamond tips or so-called buckyballs). The tip traverses the wafer, scanning the pattern on its surface (either the wafer being translated on a stage (not shown), or the cantilever being drawn across the wafer). The tip at the end of the cantilever is attracted or repelled by the features on the wafer in a direction that is substantially perpendicular to the wafer surface. The vertical translations of the tip are detected by a piezoelectric detector which generates a varying electrical signal, that is then applied to an amplifier and is evaluated by a computer (not shown).

The method for the alignment of the wafer by atomic force microscopy according to the invention is illustrated in FIG. 4 as a sequence of sub-steps of step 14 in FIG. 3. After coating the wafer in step 13, the alignment marks are detected on the wafer by AFM in step 141, FIG. 4. In step 142 the wafer is subjected to a fine alignment by the AFM module 11. (Although in general only the wafer will be moved for an adjustment, in principle also the reticle could be subject to such a fine adjustment.) After the alignment marks are correctly aligned with regard to an external reference system, i.e. the optical column comprising the reticle and the wafer is correctly positioned under the optical column, the patterns on the reticle match the patterns that already exist on the wafer and the wafer is subsequently irradiated in step 143. The signals that control the alignment of the wafer with regard to the optical column are exchanged between the AFM module 11 and the exposure tool 4 (both encompassed by a dashed rectangle as part of a single unit) over the dash-dotted line 12 in FIG. 2. After step 143 the program continues at step 15 in FIG. 3.

While the invention has been described in terms of particular structures, devices and methods, those of skill in the art will understand based on the description herein that it is not limited merely to such examples and that the full scope of the invention is properly determined by the claims that follow.

1. A lithography method for forming at least one semiconductor device on a wafer comprising the steps of:
coating a lithography resist onto said wafer in a coating means,
exposing said wafer to an irradiation through a reticle in an exposure tool,
stabilizing said lithography resist for activating chemical reaction and developing said lithography resist in said predetermined areas in a developer means so as to reveal a predetermined lithography resist pattern on the wafer surface,
stabilizing the lithography resist in a stabilization means for strengthening said pattern on the wafer surface,
performing a metrology inspection of said lithography resist pattern on said wafer surface in a metrology tool,
etching, wet processing or implanting ions into said wafer in a processing cell,
wherein in said exposing step, the reticle is aligned with respect to said wafer by atomic force microscopy in an atomic force microscopy (AFM) module.

2. Method according to claim 1, wherein the reticle is aligned based on patterns on the wafer surface that are created by a preceding lithography process.

3. A lithography apparatus for forming at least one semiconductor device with sub-micron structures on a wafer having a lithography cell, a metrology tool for performing a metrology inspection of said wafer, and a processing cell for etching, wet processing or ion implantation into said wafer, said lithography cell comprising:
coating means for coating a lithography resist onto said wafer,
an exposure tool for exposing said wafer to an irradiation through a reticle,
stabilizing means for stabilizing said lithography resist for activating chemical reaction,
developer means for developing said lithography resist in said predetermined areas in so as to reveal a predetermined lithography resist pattern on the wafer surface,
stabilization means for stabilizing the lithography resist for strengthening said pattern on the wafer surface,
a metrology tool for performing a metrology inspection of said lithography resist pattern on said wafer surface,
a processing cell for etching, wet processing or implanting ions into said wafer,
wherein said exposure tool has an atomic force microscopy (AFM) module for the alignment of said reticle to alignment marks on said wafer.

4. The lithography apparatus according to claim 3, wherein said atomic force microscopy (AFM) module comprises a plurality of styli, each at a predetermined position on the wafer.

5. Apparatus according to claim 3, wherein said atomic force microscopy module is capable of detecting patterns on the wafer surface that are created by a preceding lithography process.
